(19) United States
(12) Patent Application Publication
(10) Pub. No.: US 2025/0349560 A1
(43) Pub. Date: Nov. 13, 2025

(54) POWER SEMICONDUCTOR DEVICE AND METHOD OF MANUFACTURING POWER SEMICONDUCTOR DEVICE

(71) Applicant: Mitsubishi Electric Corporation, Tokyo (JP)

(72) Inventor: Fumihito KAWAHARA, Tokyo (JP)

(73) Assignee: Mitsubishi Electric Corporation, Tokyo (JP)

(21) Appl. No.: 19/057,922

(22) Filed: Feb. 19, 2025

(30) Foreign Application Priority Data
May 9, 2024 (JP) 2024-076321

(51) Int. Cl. H01L 21/56; H01L 23/00; H01L 23/057; H01L 23/31

(52) U.S. Cl. CPC H01L 21/56; H01L 23/057; H01L 23/3135; H01L 24/48; H01L 2224/48137; H01L 2224/48227

(57) ABSTRACT

An object is to provide a technology that can increase the mechanical strength of interconnect wires using a sealant. A power semiconductor device includes: a plurality of interconnect wires establishing at least one connection between semiconductor elements, between metal circuit patterns, or between a semiconductor element and a metal circuit pattern, the interconnect wires extending along each other; and a first sealant sealing the semiconductor elements at a height lower than the maximum height of the interconnect wires on the semiconductor elements, the first sealant covering an upper portion of the interconnect wires in a shape following a shape of the upper portion to be filled between the adjacent interconnect wires.

### BACKGROUND

### Technical Field

The present disclosure relates to a power semiconductor device, and a method of manufacturing the power semiconductor device.

### Description of the Background Art

Various technologies on power semiconductor devices in each of which a semiconductor element bonded by interconnect wires is sealed by a silicone resin inside a case have been proposed. For example, Japanese Patent Application Laid-Open No. 2011-044628 proposes a technology of temporarily raising, under a reduced pressure, an upper surface of a silicone resin provided inside a case to cover loop portions of the interconnect wires with the silicone resin.

Under the conventional art, however, the loop portions of the interconnect wires are merely covered with a thin sealant such as the silicone resin. Since the mechanical strength of the interconnect wires covered with the sealant is relatively weak, this causes a problem of a break in the interconnect wires.

### SUMMARY

The present disclosure has been conceived in view of the problem, and has an object of providing a technology that can increase the mechanical strength of interconnect wires using a sealant.

A power semiconductor device according to the present disclosure includes: at least one metal circuit pattern; at least one semiconductor element mounted on the at least one metal circuit pattern; a plurality of interconnect wires establishing at least one connection between the at least one semiconductor element, between the at least one metal circuit pattern, or between the at least one semiconductor element and the at least one metal circuit pattern, the interconnect wires extending along each other; a case surrounding the at least one semiconductor element in a plan view; and a first sealant sealing the at least one semiconductor element at a height lower than a maximum height of the interconnect wires on the at least one semiconductor element, the first sealant covering an upper portion of the interconnect wires in a shape following a shape of the upper portion to be filled between the adjacent interconnect wires.

The mechanical strength of the interconnect wires covered with the sealant can be increased.

These and other objects, features, aspects, and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view illustrating a configuration of a power semiconductor device according to Embodiment 1;

FIG. 2 is a plan view illustrating the configuration of the power semiconductor device according to Embodiment 1;

FIG. 3 is a flowchart illustrating a first method of manufacturing the power semiconductor device according to Embodiment 1;

FIG. 4 is a cross-sectional view schematically illustrating an intermediate product obtained by the first manufacturing method;

FIG. 5 is a cross-sectional view schematically illustrating an intermediate product obtained by the first manufacturing method;

FIG. 6 is a cross-sectional view schematically illustrating an intermediate product obtained by the first manufacturing method;

FIG. 7 is a cross-sectional view schematically illustrating an intermediate product obtained by the first manufacturing method;

FIG. 8 is a flowchart illustrating a second method of manufacturing a power semiconductor device according to Embodiment 1;

FIG. 9 is a cross-sectional view schematically illustrating an intermediate product obtained by the second manufacturing method;

FIG. 10 is a cross-sectional view schematically illustrating an intermediate product obtained by the second manufacturing method;

FIG. 11 is a cross-sectional view schematically illustrating an intermediate product obtained by the second manufacturing method;

FIG. 12 is a cross-sectional view illustrating a configuration of the power semiconductor device according to Embodiment 2;

FIG. 13 is a cross-sectional view illustrating a configuration of a power semiconductor device according to Embodiment 3;

FIG. 14 is a plan view illustrating the configuration of the power semiconductor device according to Embodiment 3;

FIG. 15 is a cross-sectional view illustrating a configuration of a power semiconductor device according to Embodiment 4;

FIG. 16 is a plan view illustrating the configuration of the power semiconductor device according to Embodiment 4;

FIG. 17 is a cross-sectional view illustrating a configuration of a power semiconductor device according to Embodiment 5;

FIG. 18 is a perspective view illustrating the configuration of the power semiconductor device according to Embodiment 5;

FIG. 19 is a perspective view illustrating the configuration of the power semiconductor device according to Embodiment 5;

FIG. 20 is a perspective view illustrating the configuration of the power semiconductor device according to Embodiment 5; and

FIG. 21 is a cross-sectional view illustrating a configuration of a power semiconductor device according to Embodiment 6.

### DESCRIPTION OF THE PREFERRED EMBODIMENTS

Embodiments will be described with reference to the attached drawings. The features to be described in Embodiments below are mere exemplifications, and all of the features are not necessarily essential. In the description below, identical constituent elements in a plurality of Embodiments will be denoted by the same or similar reference numerals, and different constituent elements will be mainly described. In the following description, a particular position and a particular direction such as “up”, “down”, “left”, “right”, “front”, or “back” need not always coincide with an actual position and an actual direction.

### Embodiment 1

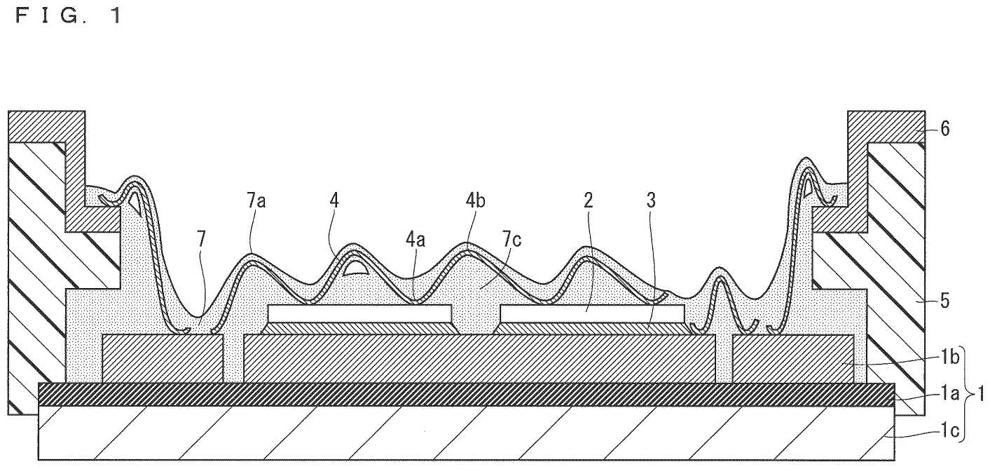

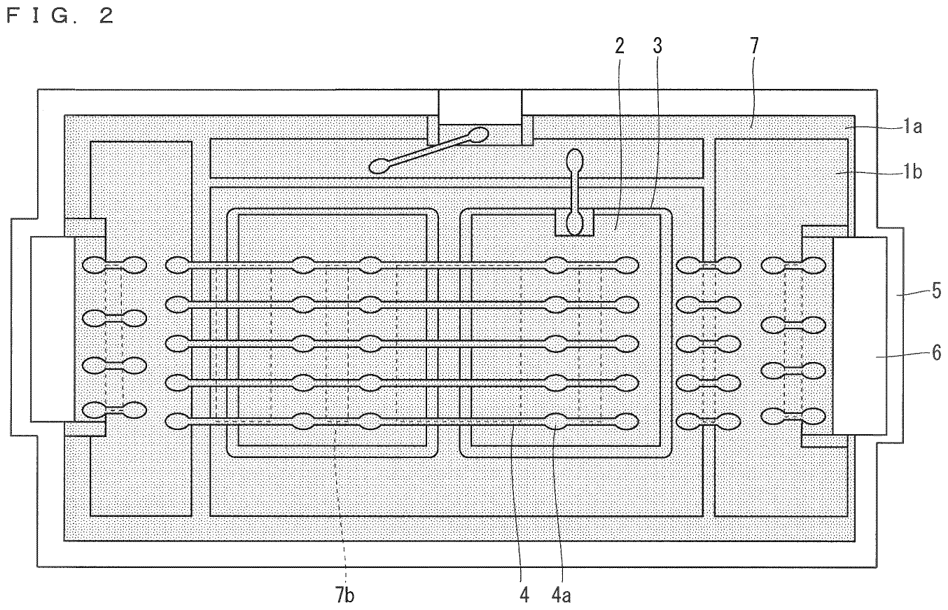

FIG. 1 and FIG. 2 are a cross-sectional view and a plan view, respectively, illustrating a configuration of a power semiconductor device according to Embodiment 1. The power semiconductor device according to Embodiment 1 includes a circuit board 1 that is a base plate, semiconductor elements 2, a bonding material 3, interconnect wires 4, a case 5, external output terminals 6, and a first sealant 7.

The circuit board 1 includes an insulating layer 1a, metal circuit patterns 1b, and a metal plate 1c. The metal circuit patterns 1b are disposed on the upper surface of the insulating layer 1a, and the metal plate 1c is disposed on the lower surface of the insulating layer 1a. For example, a direct bonded copper (DBC) substrate or an insulated metal baseplate (IMB) is used as the circuit board 1 according to Embodiment 1. The metal circuit patterns 1b may be lead frames with a transfer mold structure. Alternatively, the metal circuit patterns 1b may have a full-transfer mold structure without the insulating layer 1a and the metal plate 1c.

The semiconductor elements 2 include, for example, at least one of a metal-oxide-semiconductor field effect transistor (MOSFET), an insulated-gate bipolar transistor (IGBT), a reverse-conducting IGBT (RC-IGBT), a Schottky barrier diode (SBD), or a PN junction diode (PND). In this specification, for example, at least one of A, B, C, . . . , or Z means any one of all combinations obtained by combining one type or more extracted from each of groups of A, B, C, . . . , and Z.

The semiconductor elements 2 may be made of normal silicon (Si), or a wide bandgap semiconductor such as silicon carbide (SiC), gallium nitride (GaN), gallium oxide (Ga₂O₃), or diamond. The semiconductor elements 2 made of a wide bandgap semiconductor enable stable operations at high temperatures and high voltages, and acceleration of a switching speed.

The semiconductor elements 2 are mounted on the metal circuit patterns 1b. The number of the semiconductor elements 2 to be mounted on the metal circuit patterns 1b should be at least one. The semiconductor elements 2 transmit and receive an electric signal to and from an external device that is not illustrated, through at least one of the metal circuit patterns 1b, the interconnect wires 4, or the external output terminals 6.

The bonding material 3 electrically and mechanically connects the semiconductor elements 2 to the metal circuit patterns 1b. The bonding material 3 is, for example, solder, a sintered material, or a conductive adhesive.

The interconnect wires 4 establish at least one connection between the semiconductor elements 2, between the metal circuit patterns 1b, or between the semiconductor element 2 and the metal circuit pattern 1b. The interconnect wires 4 according to Embodiment 1 establish t not only these connections but also connections between the external output terminals 6 and the metal circuit patterns 1b.

The interconnect wires 4 are wire bonded to connection targets including the semiconductor elements 2 such that upper portions of the interconnect wires 4 have winding loop portions. FIG. 2 illustrates a joint portion 4a that is a wire bonded portion of the interconnect wire 4, using an approximately circular shape. As illustrated in FIG. 2, the interconnect wires 4 extend along each other. In other words, the interconnect wires 4 are disposed parallel or approximately parallel to each other. Although the interconnect wires 4 are made of, for example, copper or aluminum, the material is not limited to these.

The case 5 has insulating properties, and is fastened to the perimeter of the insulating layer 1a to surround the semiconductor elements 2 in a plan view. Although the case 5 includes an opening on the top in Embodiment 1, the opening of the case 5 is not essential in Embodiment 1.

The external output terminals 6 are integrally provided with the case 5, and a part of the external output terminals 6 is disposed outside of the case 5.

The first sealant 7 is an insulating thermosetting resin, and contains resin components ranging from 10 wt % to 50 wt %, and filler elements ranging from 50 wt % to 90 wt %. The first sealant 7 is surrounded by the case 5, and seals the semiconductor elements 2 at a height lower than the maximum height of the interconnect wires 4 on the semiconductor elements 2.

The first sealant 7 according to Embodiment 1 includes sealing portions 7a, 7b, and 7c. As illustrated in FIG. 1, the sealing portion 7a covers an upper portion of the interconnect wires 4 in a shape following the shape of the upper portion. As illustrated in

FIG. 2, the sealing portion 7b is filled between the adjacent interconnect wires 4. As illustrated in FIG. 1, the sealing portion 7c is filled between a portion 4b and the semiconductor element 2 or the metal circuit pattern 1b. The portion 4b has a height of a local maximum in the interconnect wires 4.

Although the first sealant 7 according to Embodiment 1 covers the entire upper portion of the interconnect wires 4 in a shape following the shape of the entire upper portion, the first sealant 7 is not limited to this. Although a thermal expansion coefficient of the first sealant 7 according to Embodiment 1 is lower than or equal to that of the interconnect wires 4, the thermal expansion coefficient of the first sealant 7 is not limited to this. Although a coefficient of elasticity of the first sealant 7 according to Embodiment 1 is lower than or equal to that of the interconnect wires 4 with a distortion of 0.2%, the coefficient of elasticity of the first sealant 7 is not limited to this.

A filler with, but not limited to, a specific gravity of 2 or higher is added to the first sealant 7 according to Embodiment 1. Although the filler according to Embodiment 1 is made of, for example, at least one of boron nitride (BN), aluminum nitride (AlN), or aluminum oxide (Al₂O₃), the material is not limited to these.

### First Manufacturing Method

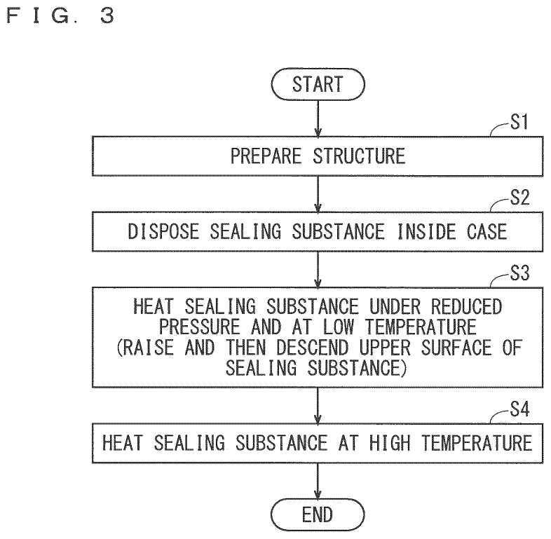

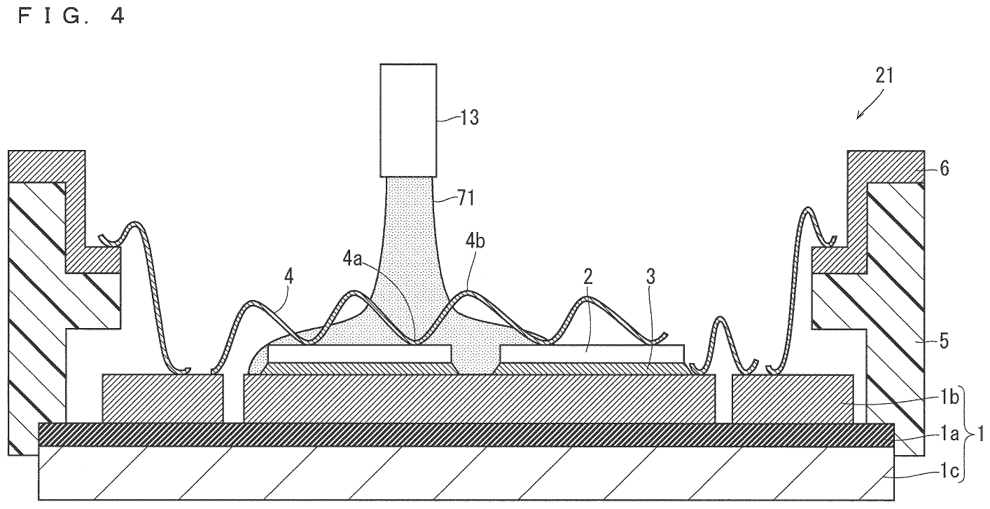

FIG. 3 is a flowchart illustrating a first method of manufacturing the power semiconductor device according to Embodiment 1. FIGS. 4 to 7 are cross-sectional views each schematically illustrating an intermediate product obtained in the course of performing the first manufacturing method.

First, in Step S1, a structure 21 including the metal circuit patterns 1b, the semiconductor elements 2, the interconnect wires 4, and the case 5 is prepared as illustrated in FIG. 4.

In Step S2, a sealing substance 71 to be the first sealant 7 is disposed inside the case 5 as illustrated in FIG. 4. FIG. 4 illustrates, but not limited to, a state of injecting the liquid sealing substance 71 into the inside of the case 5 from an injection nozzle 13 of injection equipment. For example, granules of a sealing substance that are not illustrated may be disposed inside the case 5.

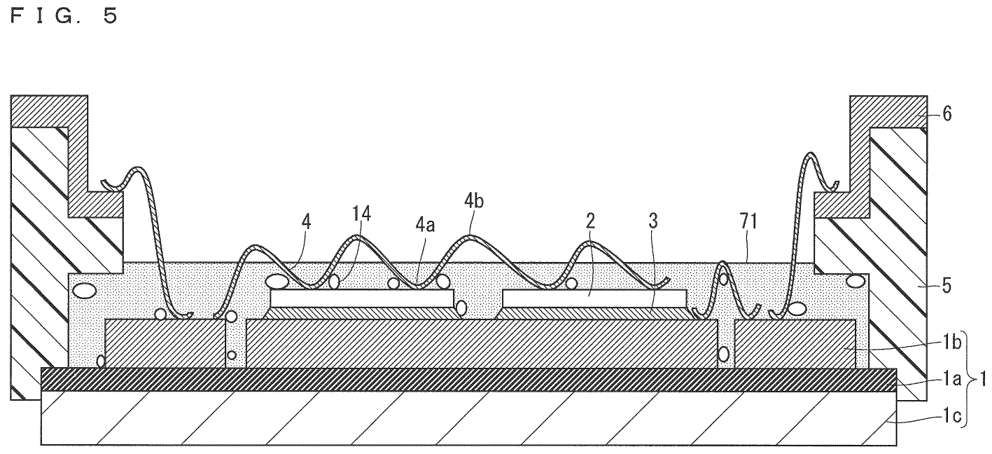

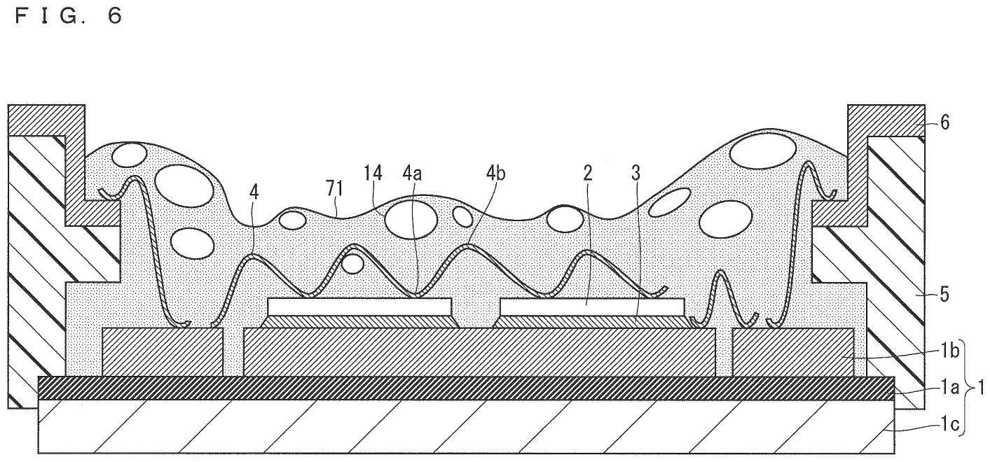

In Step S3, the sealing substance 71 is heated under a reduced pressure and at a first temperature (a low temperature). This expands bubbles 14 in the sealing substance 71 to raise the upper surface of the sealing substance 71 to above the interconnect wires 4 as illustrated in FIGS. 5 and 6. Then, removing the bubbles 14 from the sealing substance 71 descends the upper surface of the sealing substance 71. Here, the surface tension of the sealing substance 71 allows parts of the sealing substance 71 to remain at portions to be the sealing portions 7a, 7b, and 7c.

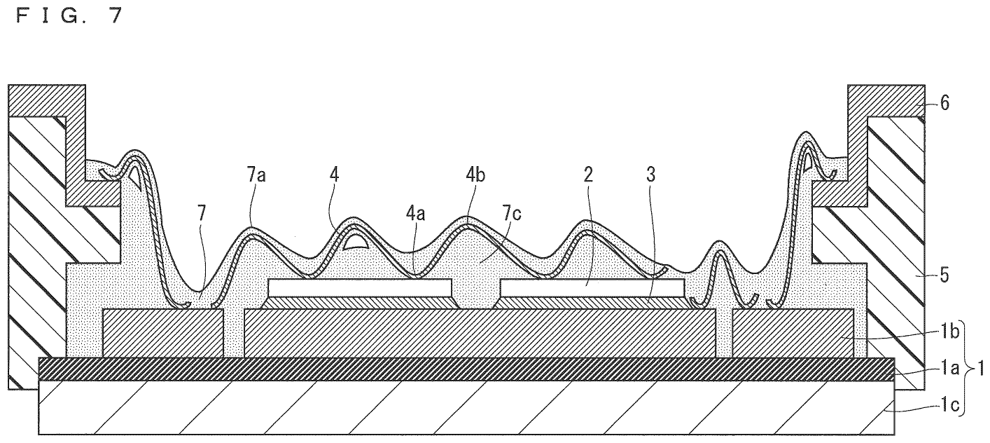

In Step S4, the sealing substance 71 heated at the first temperature is heated at a second temperature (a high temperature) higher than the first temperature as illustrated in FIG. 7. This thermally cures the sealing substance 71 to obtain the first sealant 7.

### Second Manufacturing Method

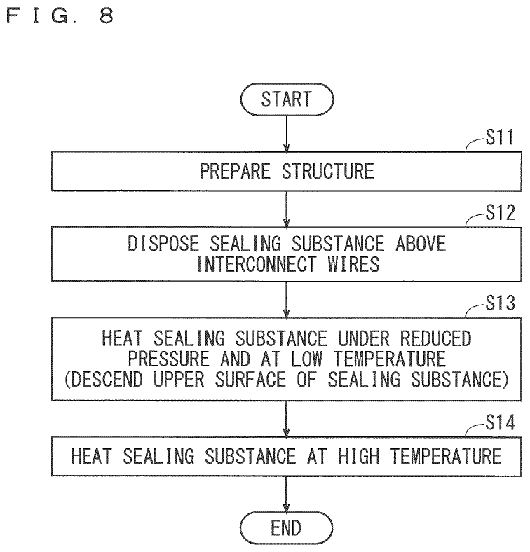

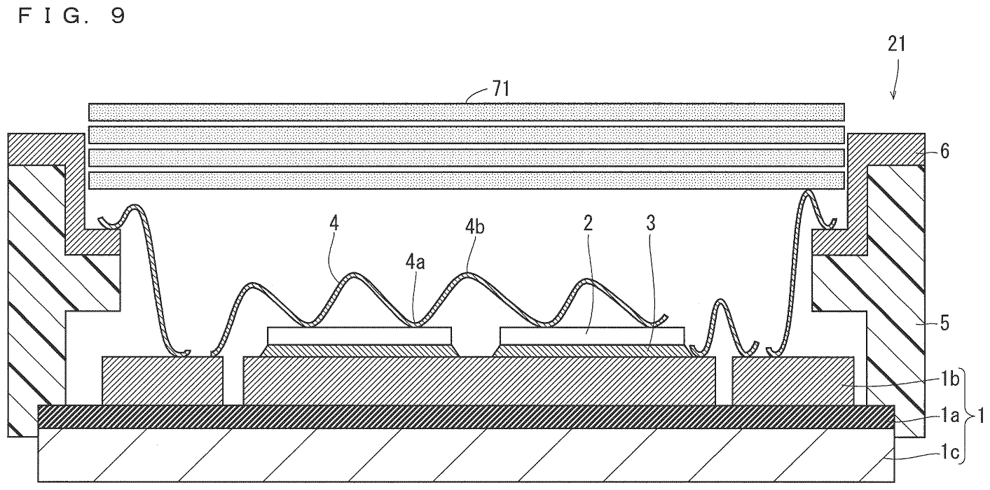

FIG. 8 is a flowchart illustrating a second method of manufacturing the power semiconductor device according to Embodiment 1. FIGS. 9 to 11 are cross-sectional views each schematically illustrating an intermediate product obtained in the course of performing the second manufacturing method.

First, in Step S11, the structure 21 including the metal circuit patterns 1b, the semiconductor elements 2, the interconnect wires 4, and the case 5 is prepared as illustrated in FIG. 9, similarly to Step S1.

In Step S12, one or more sheets of the sealing substance 71 to be the first sealant 7 are disposed above the case 5, that is, above the interconnect wires 4 as illustrated in FIG. 9.

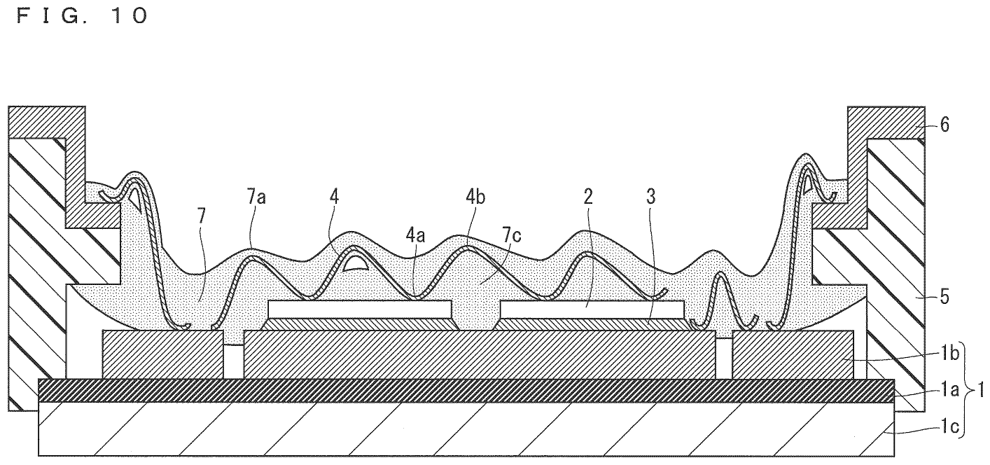

In Step S13, the sheets of the sealing substance 71 are heated under a reduced pressure and at the first temperature (a low temperature). Consequently, liquefaction of the sheets of the sealing substance 71 descends the upper surface of the sealing substance 71 as illustrated in FIG. 10. Here, the surface tension of the sealing substance 71 allows parts of the sealing substance 71 to remain at portions to be the sealing portions 7a, 7b, and 7c. Preferably, the sealing substance 71 does not entrain bubbles in this process. Even when the sealing substance 71 entrains the bubbles, the bubbles in the sealing substance 71 are removed, similarly to the first manufacturing method.

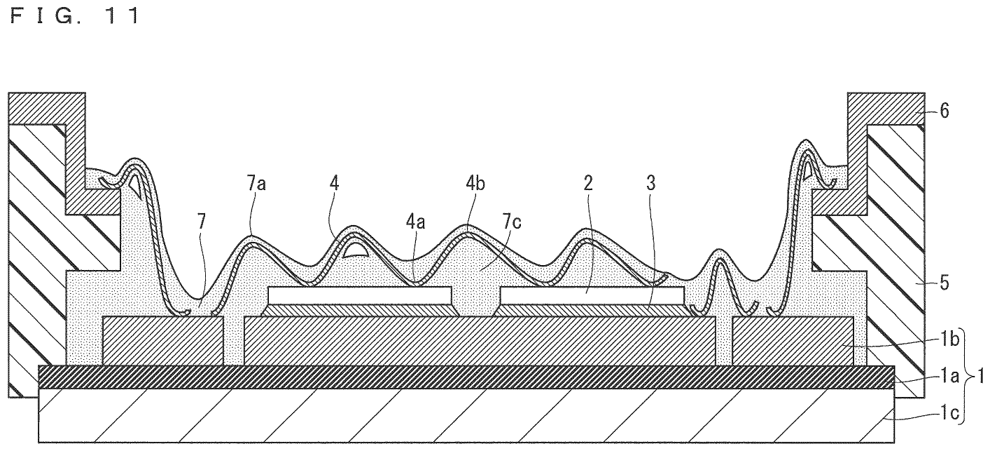

In Step S14, the sealing substance 71 heated at the first temperature is heated at the second temperature (a high temperature) higher than the first temperature as illustrated in FIG. 11. This thermally cures the sealing substance 71 to obtain the first sealant 7.

### Summary of Embodiment 1

In the power semiconductor device according to Embodiment 1, the first sealant 7 covers an upper portion of the interconnect wires 4 in a shape following the shape of the upper portion to be filled between the adjacent interconnect wires 4. Such a configuration can increase the mechanical strength of the interconnect wires 4 in an alignment direction of the adjacent interconnect wires 4, using the first sealant 7 filled between the adjacent interconnect wires 4. This can prevent a break in the interconnect wires 4.

As described in Embodiment 1, the first sealant 7 may be filled between the portion 4b with the height of the local maximum in the interconnect wires 4, and the semiconductor element 2 or the metal circuit pattern 1b. In such a configuration, the first sealant 7 constrains the entire loop portions of the interconnect wires 4. This can further increase the mechanical strength of the interconnect wires 4.

Enhancing the fillability of a sealant requires heating the sealant to reduce the viscosity, but the viscosity is relatively high at that moment. Thus, when the sealant is particularly thick, the sealant is cured with bubbles being trapped inside the sealant. This sometimes results in a decrease in the dielectric withstanding voltage.

Thus, the first sealant 7 seals the semiconductor elements 2 at a height lower than the maximum height of the interconnect wires 4 on the semiconductor elements 2. Preferably, the first sealant 7 is thin enough to cover the entire upper portion of the interconnect wires 4 in a shape following the shape of the entire upper portion. Such a configuration can improve the escapability of bubbles before the first sealant 7 is cured, and enhances the fillability of the first sealant 7. Thus, the dielectric withstanding voltage between portions to which different voltages are applied (hereinafter referred to as “between different potentials”) can be increased. Since the filling amount of the first sealant 7 can be reduced, the weight of the power semiconductor device can be reduced. Moreover, flying off of the first sealant 7 outside the case 5 when bubbles escape from the first sealant 7 can be prevented.

In Embodiment 1, the thermal expansion coefficient of the first sealant 7 is lower than or equal to that of the interconnect wires 4. Such a configuration reduces the amount of deformation in the first sealant 7 covering the interconnect wires 4 more than that of the interconnect wires 4 in thermal expansion during temperature cycling times. Thus, deformation and a break in the interconnect wires 4 can be prevented.

In Embodiment 1, a coefficient of elasticity of the first sealant 7 is lower than or equal to that of the interconnect wires 4 with a distortion of 0.2%. In such a configuration, mitigating the deformation of the interconnect wires 4 which occurs during the temperature cycling times can reduce the internal stress of the interconnect wires 4. Thus, a break in the interconnect wires 4 can be prevented.

The filler with a specific gravity of 2 or higher is added to the first sealant 7 in Embodiment 1. Here, a high specific gravity filler inside a sealant is typically susceptible to sedimentation before the filler is cured. Since the first sealant 7 is relatively thin in Embodiment 1, the first sealant 7 is less susceptible to sedimentation of a filler. This can mitigate the internal stress of the first sealant 7, which occurs due to a difference in the content of the filler between the upper portion and the lower portion of the first sealant 7.

The filler added to the first sealant 7 in Embodiment 1 is made of, for example, at least one of boron nitride (BN), aluminum nitride (AlN), or aluminum oxide (Al₂O₃). Such a configuration can expectedly make the temperature of the upper portion of each of the semiconductor elements 2 uniform, improve the heat dissipation properties, and reduce the thermal stress.

According to the first manufacturing method in Embodiment 1, the sealing substance 71 is heated under a reduced pressure and at the first temperature to raise the upper surface of the sealing substance 71 inside the case 5 to above the interconnect wires 4, and then the upper surface is descended. Such a configuration can readily form the first sealant 7 which covers the upper portion of the interconnect wires 4 in a shape following the shape of the upper portion and is filled between the adjacent interconnect wires 4.

According to the second manufacturing method in Embodiment 1, the sealing substance 71 disposed above the interconnect wires 4 is heated under a reduced pressure and at the first temperature to descend the upper surface of the sealing substance 71. Such a configuration can readily form the first sealant 7 which covers the upper portion of the interconnect wires 4 in a shape following the shape of the upper portion and is filled between the adjacent interconnect wires 4.

### Embodiment 2

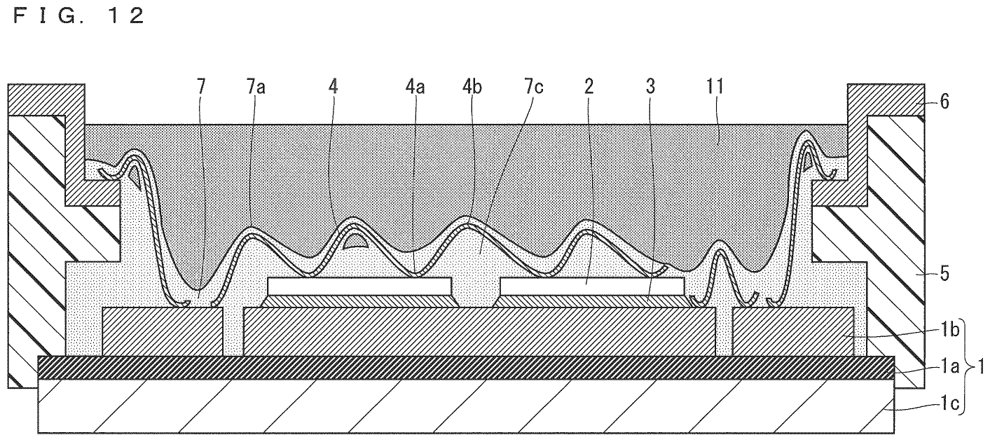

FIG. 12 is a cross-sectional view illustrating a configuration of a power semiconductor device according to Embodiment 2. A configuration according to Embodiment 2 is obtained by adding a second sealant 11 that is an insulating thermosetting resin to the configuration in FIG. 1.

The second sealant 11 covers an upper portion of the first sealant 7. Since such a configuration can increase an insulation distance between different potentials, the dielectric withstanding voltage between the different potentials can be increased.

The viscosity of a curing agent included in the second sealant 11 to be cured may be lower than that of a curing agent included in the first sealant 7 to be cured. Such a configuration can cover the first sealant 7 with the second sealant 11 whose bubbles are removed more readily than those of the first sealant 7 in manufacturing. Thus, the dielectric withstanding voltage between the different potentials can be further increased.

Furthermore, the molecular weight of the curing agent included in the second sealant 11 to be cured may be less than that of the curing agent included in the first sealant 7 to be cured. At the completion of a power semiconductor device, the molecular weight of the curing agent included in the second sealant 11 may be less than that of the curing agent included in the first sealant 7. Even such a configuration can cover the first sealant 7 with the second sealant 11 whose bubbles are removed more readily than those of the first sealant 7 in manufacturing. Thus, the dielectric withstanding voltage between the different potentials can be further increased.

Furthermore, the second sealant 11 may be made of the same material as that of the first sealant 7. Such a configuration can manage the sealant with ease.

### Embodiment 3

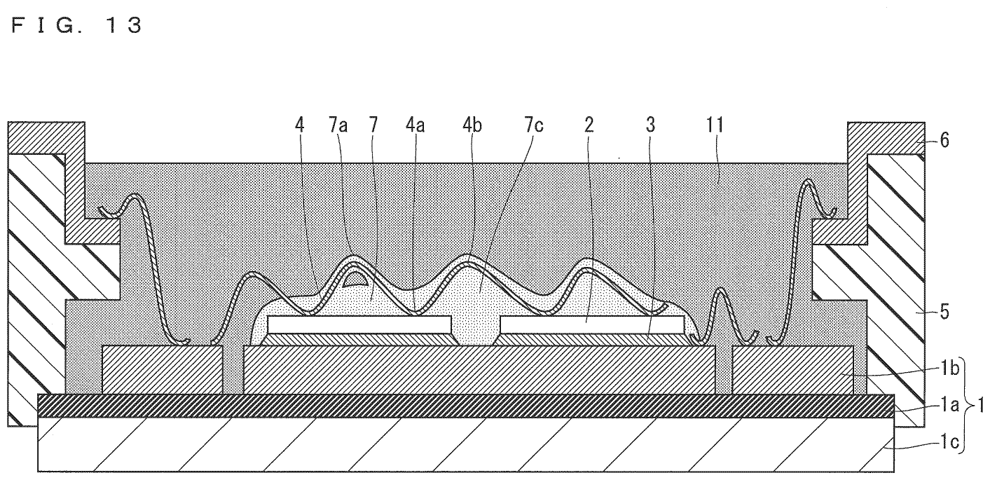

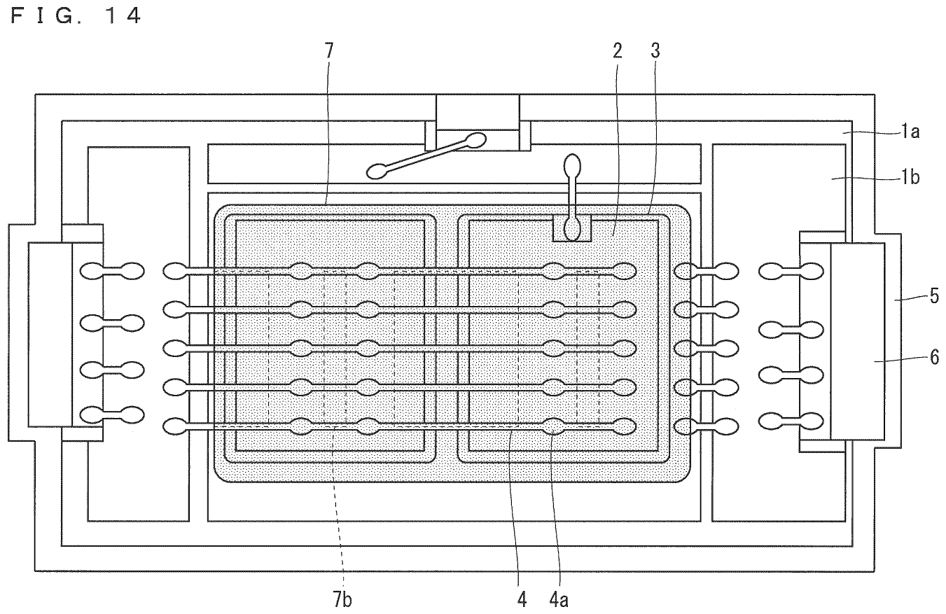

FIG. 13 and FIG. 14 are a cross-sectional view and a plan view, respectively, illustrating a configuration of a power semiconductor device according to Embodiment 3. FIG. 14 omits the illustration of the second sealant 11.

In Embodiment 3, the first sealant 7 is provided only on or above the metal circuit patterns 1b bonded to the semiconductor elements 2 in a plan view. Other configurations are identical to those according to Embodiment 2.

Such a configuration allows the second sealant 11 to be filled between the metal circuit patterns 1b. Thus, when the second sealant 11 is made of a material that facilitates removing bubbles more than that of the first sealant 7 in manufacturing, the dielectric withstanding voltage between the different potentials that are between the metal circuit patterns 1b can be increased.

### Embodiment 4

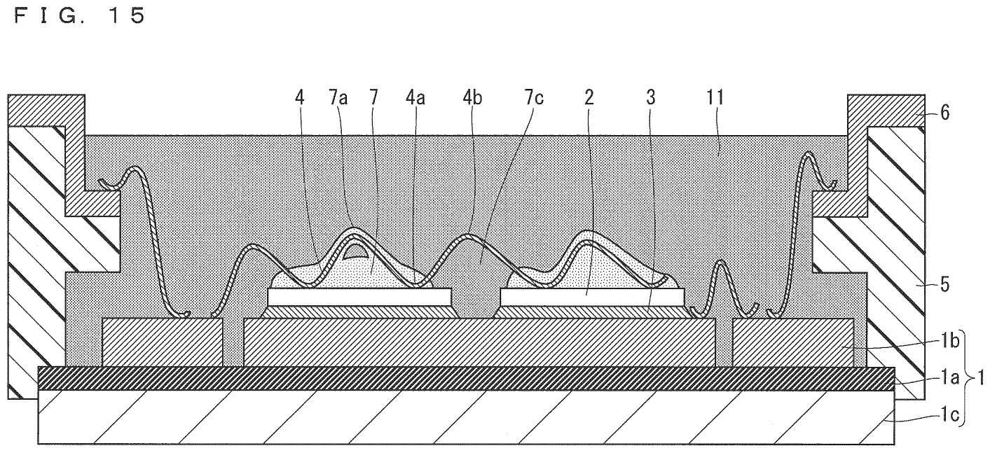

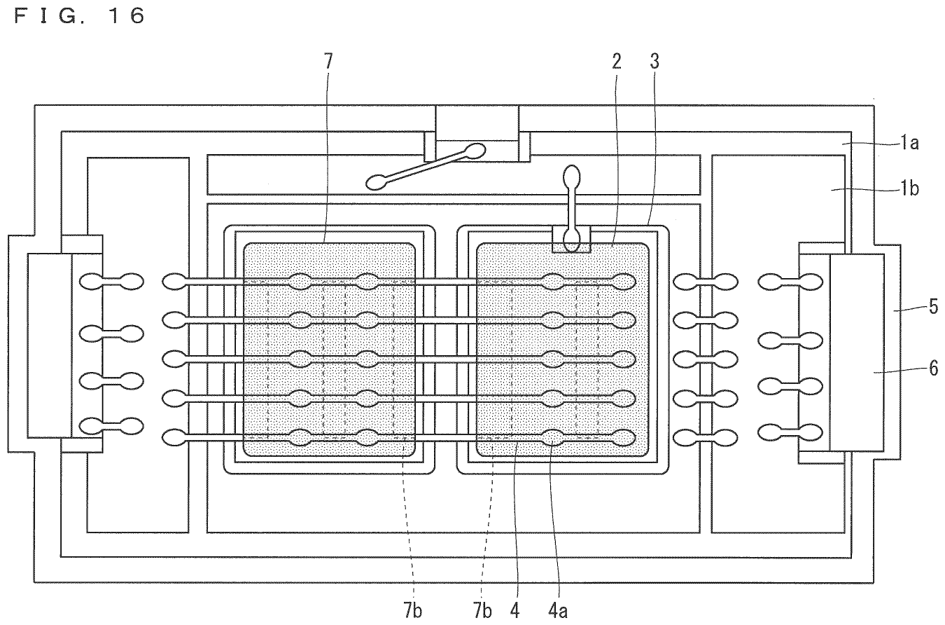

FIG. 15 and FIG. 16 are a cross-sectional view and a plan view, respectively, illustrating a configuration of a power semiconductor device according to Embodiment 4. FIG. 16 omits the illustration of the second sealant 11.

In Embodiment 4, the first sealant 7 is provided only on the semiconductor elements 2 in a plan view. Other configurations are identical to those according to Embodiment 2.

Such a configuration allows the second sealant 11 to be filled between the semiconductor elements 2. Thus, when the second sealant 11 is made of a material that facilitates removing bubbles more than that of the first sealant 7 in manufacturing, the dielectric withstanding voltage between the different potentials that are between the semiconductor elements 2 can be increased.

### Embodiment 5

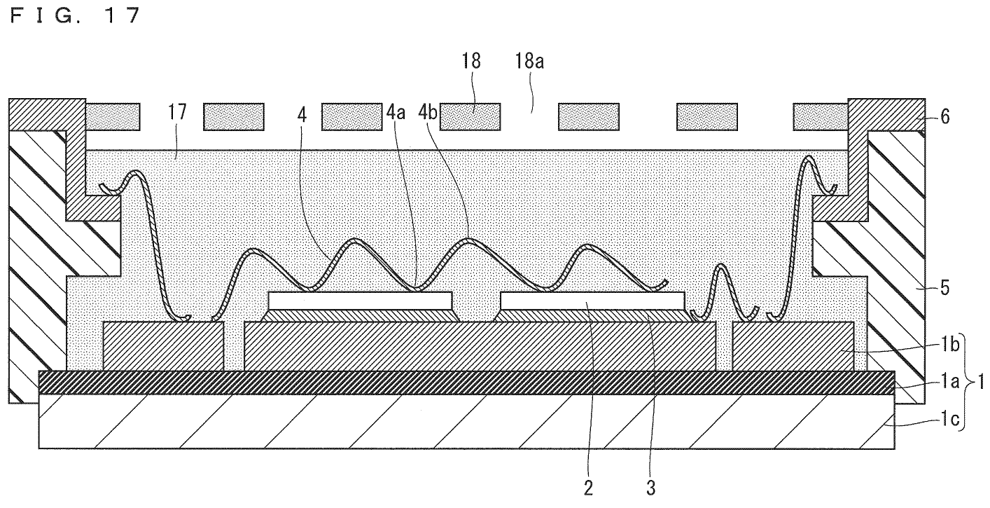

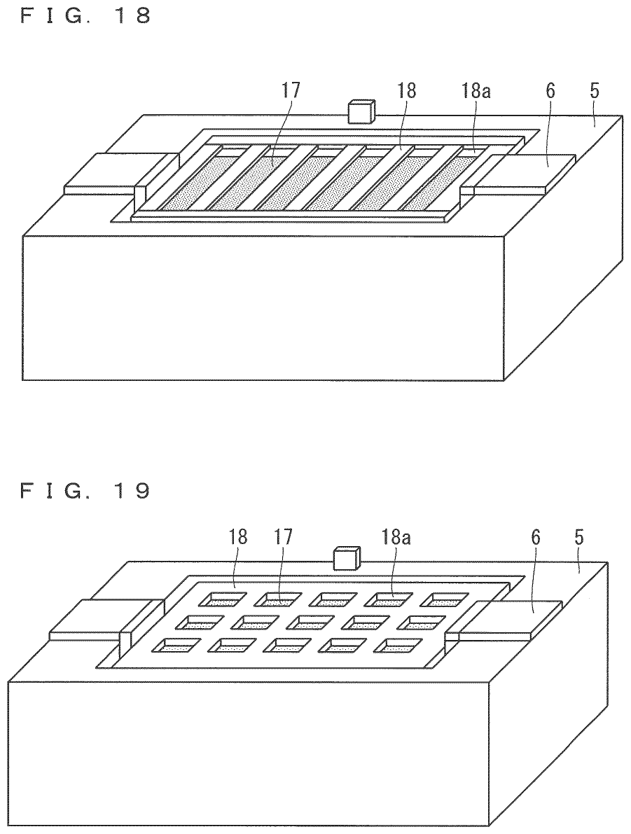

FIG. 17 is a cross-sectional view illustrating a configuration of a power semiconductor device according to Embodiment 5. FIGS. 18 to 20 are perspective views schematically illustrating the configuration of the semiconductor device according to Embodiment 5. A configuration according to Embodiment 5 is obtained by providing a sealant 17 that is an insulating thermosetting resin instead of the first sealant 7 and adding a lid 18 to the configuration in FIG. 1.

The sealant 17 is surrounded by the case 5, and seals the semiconductor elements 2. The upper surface of the sealant 17 is almost planar, unlike the upper surface of the first sealant 7. The lid 18 is disposed on the opening of the case 5, and includes a plurality of through holes 18a.

In an attempt to remove bubbles in the sealant 17 to be cured by expanding the bubbles through heating under a reduced pressure according to the first manufacturing method as described in Embodiment 1, the bubbles raise the upper surface of the sealant 17. In the power semiconductor device according to Embodiment 5, corners in an outer edge of each of the through holes 18a in a lower portion of the lid 18 can hit the rising bubbles to break the bubbles. This can prevent the sealant 17 from overflowing outside the case 5 and prevent the bubbles from remaining in the sealant 17.

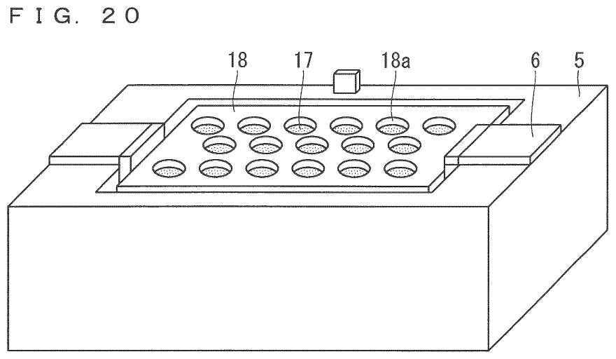

The lid 18 may be a part of the case 5 to reduce the number of parts of the power semiconductor device. The through holes 18a may be, for example, slits as illustrated in FIG. 18, polygonal as illustrated in FIG. 19, circular as illustrated in FIG. 20, or may have shapes other than these. Embodiment 5 may be applied to Embodiments 1 to 4.

### Embodiment 6

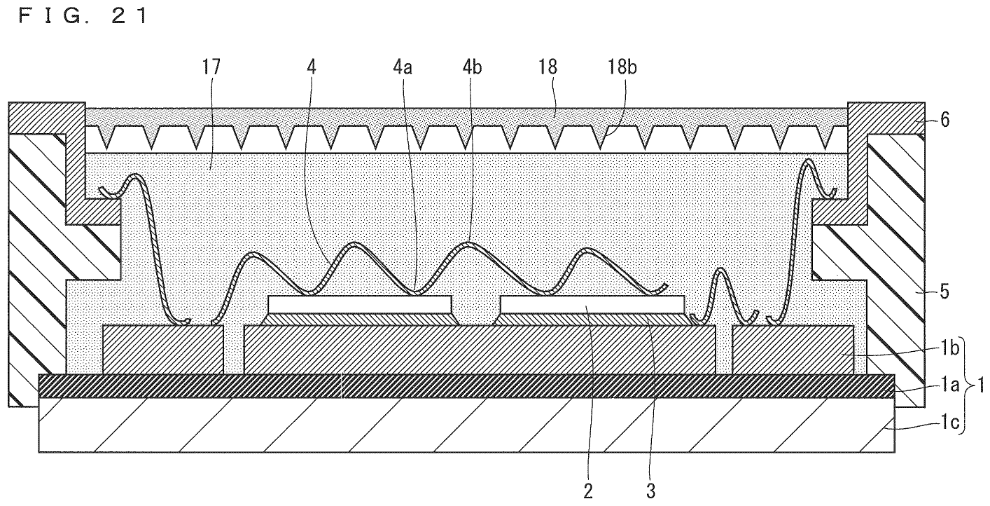

FIG. 21 is a cross-sectional view illustrating a configuration of a power semiconductor device according to Embodiment 6. In Embodiment 6, a plurality of protrusions 18b tapered toward the sealant 17 are provided on a surface of the lid 18 that is a surface closer to the sealant 17, instead of the plurality of through holes 18a of the lid 18 in the configuration of FIG. 17.

In the power semiconductor device according to Embodiment 6, the protrusions 18b of the lid 18 can hit the rising bubbles to break the bubbles. This can prevent the sealant 17 from overflowing outside the case 5 and prevent the bubbles from remaining in the sealant 17. Since the lid 18 almost completely closes the opening of the case 5 in the configuration in FIG. 21, flying off of the sealant 17 outside the case 5 can be prevented.

The lid 18 may be a part of the case 5 to reduce the number of parts of the power semiconductor device. The protrusions 18b may be provided only on a portion below which the upper surface of the sealant 17 tends to rise. Embodiment 6 may be applied to Embodiments 1 to 4.

In this English disclosure, the articles “a” and “an” mean one or more. Thus, “a”, “an”, “one or more”, and “at least one” can be used in the same meaning.

Embodiments and the modifications can be freely combined, and appropriately modified or omitted.

A summary of various aspects of the present disclosure will be hereinafter described as Appendixes.

### Appendix 1

A power semiconductor device, comprising:
at least one metal circuit pattern;
at least one semiconductor element mounted on the at least one metal circuit pattern;
a plurality of interconnect wires establishing at least one connection between the at least one semiconductor element, between the at least one metal circuit pattern, or between the at least one semiconductor element and the at least one metal circuit pattern, the interconnect wires extending along each other;
a case surrounding the at least one semiconductor element in a plan view; and
a first sealant sealing the at least one semiconductor element at a height lower than a maximum height of the interconnect wires on the at least one semiconductor element, the first sealant covering an upper portion of the interconnect wires in a shape following a shape of the upper portion to be filled between the adjacent interconnect wires.

### Appendix 2

The power semiconductor device according to appendix 1,
wherein a thermal expansion coefficient of the first sealant is lower than or equal to a thermal expansion coefficient of the interconnect wires.

### Appendix 3

The power semiconductor device according to appendix 1 or 2,
wherein a coefficient of elasticity of the first sealant is lower than or equal to a coefficient of elasticity of the interconnect wires with a distortion of 0.2%.

### Appendix 4

The power semiconductor device according to any one of appendixes 1 to 3, further comprising
a second sealant covering an upper portion of the first sealant.

### Appendix 5

The power semiconductor device according to appendix 4,
wherein the first sealant is provided only on or above the at least one metal circuit pattern bonded to the at least one semiconductor element in the plan view.

### Appendix 6

The power semiconductor device according to appendix 4 or 5,
wherein a molecular weight of a curing agent included in the second sealant is less than a molecular weight of a curing agent included in the first sealant.

### Appendix 7

The power semiconductor device according to appendix 4,
wherein the first sealant is provided only on the at least one semiconductor element in the plan view.

### Appendix 8

The power semiconductor device according to any one of appendixes 1 to 7,
wherein a filler with a specific gravity of 2 or higher is added to the first sealant.

### Appendix 9

A power semiconductor device, comprising:
a semiconductor element;
a case surrounding the semiconductor element in a plan view, the case including an opening on a top;
a sealant surrounded by the case and sealing the semiconductor element; and
a lid on the opening of the case,
wherein the lid includes a plurality of through holes.

### Appendix 10

A power semiconductor device, comprising:
a semiconductor element;
a case surrounding the semiconductor element in a plan view, the case including an opening on a top;
a sealant surrounded by the case and sealing the semiconductor element; and a lid on the opening of the case,
wherein a plurality of protrusions tapered toward the sealant are provided on a surface of the lid which is a surface closer to the sealant.

### Appendix 11

A method of manufacturing the power semiconductor device according to any one of appendixes 1 to 8, the method comprising the steps of:
preparing a structure including the at least one metal circuit pattern, the at least one semiconductor element, the interconnect wires, and the case;
disposing, inside the case, a sealing substance to be the first sealant;
heating the sealing substance under a reduced pressure and at a first temperature to raise an upper surface of the sealing substance to above the interconnect wires, and then descending the upper surface; and
heating, at a second temperature higher than the first temperature, the sealing substance heated at the first temperature to form the first sealant.

### Appendix 12

A method of manufacturing the power semiconductor device according to any one of appendixes 1 to 8, the method comprising the steps of:
preparing a structure including the at least one metal circuit pattern, the at least one semiconductor element, the interconnect wires, and the case;
disposing, above the interconnect wires, a sealing substance to be the first sealant;
heating the sealing substance under a reduced pressure and at a first temperature to descend an upper surface of the sealing substance; and
heating, at a second temperature higher than the first temperature, the sealing substance heated at the first temperature to form the first sealant.

### Appendix 13

A method of manufacturing the power semiconductor device according to appendix 4 or 5,
wherein a viscosity of a curing agent included in the second sealant to be cured is lower than a viscosity of a curing agent included in the first sealant to be cured.

### Appendix 14

A method of manufacturing the power semiconductor device according to appendix 4 or 5,
wherein a molecular weight of a curing agent included in the second sealant to be cured is less than a molecular weight of a curing agent included in the first sealant to be cured.

While the disclosure has been shown and described in detail, the foregoing description is in all aspects illustrative and not restrictive. It is therefore understood that numerous modifications and variations can be devised.

What is claimed is:

1. A power semiconductor device, comprising:
at least one metal circuit pattern;
at least one semiconductor element mounted on the at least one metal circuit pattern;
a plurality of interconnect wires establishing at least one connection between the at least one semiconductor element, between the at least one metal circuit pattern, or between the at least one semiconductor element and the at least one metal circuit pattern, the interconnect wires extending along each other;
a case surrounding the at least one semiconductor element in a plan view; and
a first sealant sealing the at least one semiconductor element at a height lower than a maximum height of the interconnect wires on the at least one semiconductor element, the first sealant covering an upper portion of the interconnect wires in a shape following a shape of the upper portion to be filled between the adjacent interconnect wires.

2. The power semiconductor device according to claim 1,
wherein a thermal expansion coefficient of the first sealant is lower than or equal to a thermal expansion coefficient of the interconnect wires.

3. The power semiconductor device according to claim 1,
wherein a coefficient of elasticity of the first sealant is lower than or equal to a coefficient of elasticity of the interconnect wires with a distortion of 0.2%.

4. The power semiconductor device according to claim 1, further comprising
a second sealant covering an upper portion of the first sealant.

5. The power semiconductor device according to claim 4,
wherein the first sealant is provided only on or above the at least one metal circuit pattern bonded to the at least one semiconductor element in the plan view.

6. The power semiconductor device according to claim 4,
wherein a molecular weight of a curing agent included in the second sealant is less than a molecular weight of a curing agent included in the first sealant.

7. The power semiconductor device according to claim 4,
wherein the first sealant is provided only on the at least one semiconductor element in the plan view.

8. The power semiconductor device according to claim 1,
wherein a filler with a specific gravity of 2 or higher is added to the first sealant.

9. A power semiconductor device, comprising:
a semiconductor element;
a case surrounding the semiconductor element in a plan view, the case including an opening on a top;
a sealant surrounded by the case and sealing the semiconductor element; and
a lid on the opening of the case,
wherein the lid includes a plurality of through holes.

10. A power semiconductor device, comprising:
a semiconductor element;
a case surrounding the semiconductor element in a plan view, the case including an opening on a top;
a sealant surrounded by the case and sealing the semiconductor element; and
a lid on the opening of the case,
wherein a plurality of protrusions tapered toward the sealant are provided on a surface of the lid which is a surface closer to the sealant.

11. A method of manufacturing the power semiconductor device according to claim 1, the method comprising the steps of:
preparing a structure including the at least one metal circuit pattern, the at least one semiconductor element, the interconnect wires, and the case;
disposing, inside the case, a sealing substance to be the first sealant;
heating the sealing substance under a reduced pressure and at a first temperature to raise an upper surface of the sealing substance to above the interconnect wires, and then descending the upper surface; and
heating, at a second temperature higher than the first temperature, the sealing substance heated at the first temperature to form the first sealant.

12. A method of manufacturing the power semiconductor device according to claim 1, the method comprising the steps of:
preparing a structure including the at least one metal circuit pattern, the at least one semiconductor element, the interconnect wires, and the case;
disposing, above the interconnect wires, a sealing substance to be the first sealant;
heating the sealing substance under a reduced pressure and at a first temperature to descend an upper surface of the sealing substance; and
heating, at a second temperature higher than the first temperature, the sealing substance heated at the first temperature to form the first sealant.

13. A method of manufacturing the power semiconductor device according to claim 4,
wherein a viscosity of a curing agent included in the second sealant to be cured is lower than a viscosity of a curing agent included in the first sealant to be cured.

14. A method of manufacturing the power semiconductor device according to claim 4,
wherein a molecular weight of a curing agent included in the second sealant to be cured is less than a molecular weight of a curing agent included in the first sealant to be cured.
